(19) United States
(12) Patent Application Publication
(10) Pub. No.: US 2025/0275329 A1
(43) Pub. Date: Aug. 28, 2025

(54) LIGHT EMITTING ELEMENT

(71) Applicant: NICHIA CORPORATION, Anan-shi (JP)

(72) Inventor: Naoto FURUHA, Kaifu-gun (JP)

(73) Assignee: NICHIA CORPORATION, Anan-shi (JP)

(21) Appl. No.: 19/061,751

(22) Filed: Feb. 24, 2025

(30) Foreign Application Priority Data
Feb. 27, 2024 (JP) 2024-027681

(51) Int. Cl. H10H 29/14; H10H 29/01; H10H 29/80; H10H 29/85

(52) U.S. Cl. CPC H10H 29/142; H10H 29/011; H10H 29/032; H10H 29/034; H10H 29/8321; H10H 29/842; H10H 29/857

(57) ABSTRACT

A light emitting element includes a semiconductor stack structure, a first electrode, a second electrode, and an insulation layer. The semiconductor stack structure includes a first p-type semiconductor layer, a first active layer, a first n-type semiconductor layer, an intermediate layer, a second p-type semiconductor layer, a second active layer, and a second n-type semiconductor layer. The semiconductor stack structure includes a first opening and a second opening. The first opening is provided continuously in the first p-type semiconductor layer and the first active layer. The second opening in a plan view is located to overlap the first opening. The second opening is provided continuously in the first n-type semiconductor layer, the intermediate layer, the second p-type semiconductor layer, and the second active layer.

### CROSS-REFERENCE TO RELATED APPLICATION

This application claims priority to Japanese Patent Application No. 2024-027681, filed on Feb. 27, 2024, the disclosure of which is hereby incorporated by reference in its entirety.

### BACKGROUND

An embodiment of the present disclosure relates to a light emitting element.

U.S. Patent Publication No. 2009/0001389 discloses a structure in which a first LED including a green light emitting first active region and a second LED including a blue light emitting second active region are stacked via a tunnel junction.

### SUMMARY

An object of an embodiment of the present disclosure is to provide a light emitting element capable of reducing light distribution variation between the first active layer and the second active layer.

A light emitting element according to one embodiment of the present

disclosure has a semiconductor stack structure, a first electrode, a second electrode, and an insulation layer. The semiconductor stack structure has a first p-type semiconductor layer, a first active layer, a first n-type semiconductor layer, an intermediate layer, a second p-type semiconductor layer, a second active layer, and a second n-type semiconductor layer. The first active layer is disposed on the first p-type semiconductor layer. The first n-type semiconductor layer is disposed on the first active layer. The intermediate layer is disposed on the first n-type semiconductor layer. The second p-type semiconductor layer is disposed on the intermediate layer. The second active layer is disposed on the second p-type semiconductor layer. The second n-type semiconductor layer is disposed on the second active layer. The semiconductor stack structure has a first opening and a second opening. The first opening is provided continuously in the first p-type semiconductor layer and the first active layer. The second opening in a plan view is located to overlap the first opening. The second opening is provided continuously in the first n-type semiconductor layer, the intermediate layer, the second p-type semiconductor layer, and the second active layer. The first electrode is located in the first opening. The first electrode is electrically connected to the first n-type semiconductor layer. The second electrode is located in the first opening and the second opening. The second electrode is electrically connected to the second n-type semiconductor layer. The insulation layer is disposed between the first electrode and the second electrode. The insulation layer is in contact with the first electrode and the second electrode.

According to an embodiment of the present disclosure, a light emitting element capable of reducing light distribution variation between the first active layer and the second active layer can be provided.

### BRIEF DESCRIPTION OF THE DRAWINGS

FIG. 1 is a plan view showing a light emitting element according to a first embodiment.

FIG. 2 is a cross-sectional view of the light emitting element according to the first embodiment.

FIG. 3 is a cross-sectional view of the current path in a first emission state of the light emitting element according to the first embodiment.

FIG. 4 is a cross-sectional view of the current path in a second emission state of the light emitting element according to the first embodiment.

FIG. 5 is a cross-sectional view of the current path in a third emission state of the light emitting element according to the first embodiment.

FIG. 6 is a plan view of a light emitting element according to a variation of the first embodiment.

FIG. 7 is a cross-sectional view of the light emitting element according to the variation of the first embodiment.

FIG. 8 is a plan view of a light emitting element according to a second embodiment.

FIG. 9 is a cross-sectional view of the light emitting element according to the second embodiment.

FIG. 10 is a plan view of a light emitting element according to a variation of the second embodiment.

FIG. 11 is a plan view of a light emitting element according to a third embodiment.

FIG. 12 is a plan view of a light emitting element according to a variation of the third embodiment.

FIG. 13 is a cross-sectional view showing a part of a method of manufacturing a light emitting element according to the first embodiment.

FIG. 14 is a cross-sectional view showing a part of the method of manufacturing a light emitting element according to the first embodiment.

FIG. 15 is a cross-sectional view showing a part of the method of manufacturing a light emitting element according to the first embodiment.

FIG. 16 is a cross-sectional view showing a part of the method of manufacturing a light emitting element according to the first embodiment.

FIG. 17 is a cross-sectional view showing a part of the method of manufacturing a light emitting element according to the first embodiment.

### EMBODIMENTS

Certain embodiments of the present disclosure will be described below with reference to the accompanying drawings.

The drawings are schematic or conceptual. Consequently, the relationships of the thicknesses and the widths between the members or the size ratio of the members might not necessarily be the same as those in reality. Even when showing the same portion, the dimensions of or the ratio between the members might be different depending on the drawing.

In the present specification and the drawings, the elements that are similar to those which have been described using a drawing previously referenced are denoted by the same reference numerals for which detailed explanation will be omitted as appropriate.

In the description below, an XYZ orthogonal coordinate system is employed to explain the layout and the structure of each part or portion for explanation purposes. The X-axis, Y-axis, and Z-axis are orthogonal to one another. The direction in which the X-axis extends is designated as “X direction,” and the direction in which the Y-axis extends is designated as “Y direction,” and the direction in which the Z-axis extends is designated as “Z direction.” In the Z direction, the direction indicated by the arrow may be referred to as upward and the direction opposite thereto may also be referred to as downward to make the explanation more easily understood, but these directions are irrespective of the direction of gravity. A “plan view” refers to a view when viewing an object along the Z direction.

### First Embodiment

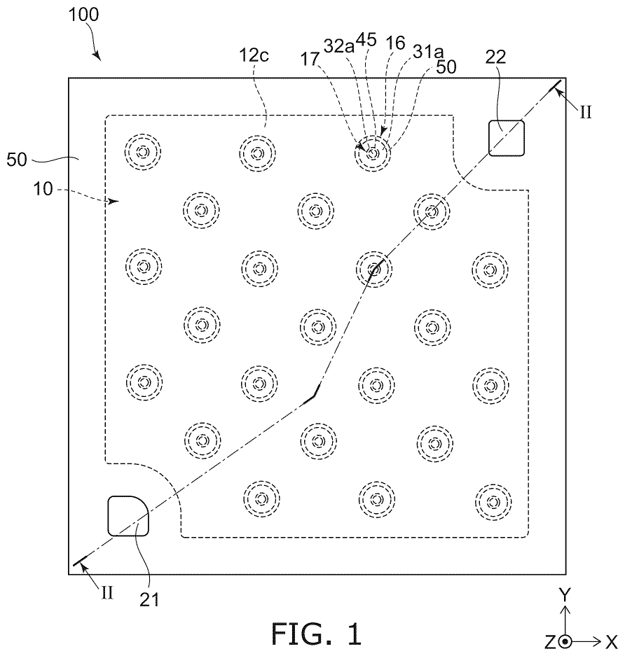

FIG. 1 is a plan view showing a light emitting element according to a first embodiment.

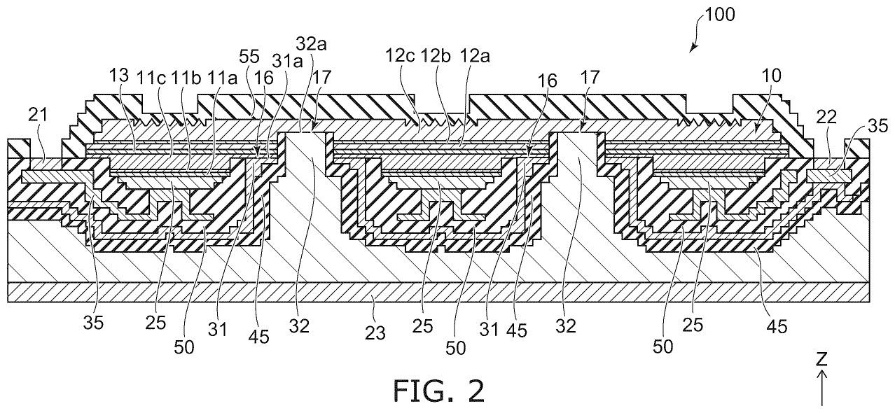

FIG. 2 is a cross-sectional view of the light emitting element according to the first embodiment.

FIG. 2 is a cross section taken along line II-II in FIG. 1.

As shown in FIG. 1 and FIG. 2, a light emitting element 100 according to the first embodiment includes a semiconductor stack structure 10, a first pad electrode 21, a second pad electrode 22, a lower electrode 23, a first electrode 31, a second electrode 32, a connection electrode 53, and an insulation layer 45.

As shown in FIG. 1, the plan view shape of the light emitting element 100 is quadrangular. In the case in which the plan view shape of the light emitting element 100 is quadrangular, the length of a side of the quadrangle is, for example, 50 μm to 2000 μm.

The semiconductor stack structure 10 has a first p-type semiconductor layer 11a, a first active layer 11b, a first n-type semiconductor layer 11c, an intermediate layer 13, a second p-type semiconductor layer 12a, a second active layer 12b, and a second n-type semiconductor layer 12c. The first active layer 11b, the first n-type semiconductor layer 11c, the intermediate layer 13, the second p-type semiconductor layer 12a, and the second active layer 12b are positioned between the first p-type semiconductor layer 11a and the second n-type semiconductor layer 12c.

The first p-type semiconductor layer 11a is disposed at the lowermost portion of the semiconductor stack structure 10. The first active layer 11b is disposed on the first p-type semiconductor layer 11a. The first n-type semiconductor layer 11c is disposed on the first active layer 11b. The intermediate layer 13 is disposed on the first n-type semiconductor layer 11c. The second p-type semiconductor layer 12a is disposed on the intermediate layer 13. The second active layer 12b is disposed on the second p-type semiconductor layer 12a. The second n-type semiconductor layer 12c is disposed on the second active layer 12b.

The first p-type semiconductor layer 11a, the first active layer 11b, the first n-type semiconductor layer 11c, the intermediate layer 13, the second p-type semiconductor layer 12a, the second active layer 12b, and the second n-type semiconductor layer 12c are each formed of a nitride semiconductor, for example. In the present specification, “nitride semiconductors” include semiconductors of all compositions obtained by varying the composition ratio x and y within their ranges in the chemical formula InₓAl_{y}Ga_{1-x-y}N (0≤x≤1, 0≤y≤1, x+y≤1). Moreover, those further containing a group V element in addition to nitrogen (N), and those further containing various elements added for controlling various physical properties such as conductivity type are also included in “nitride semiconductors.”

The first n-type semiconductor layer 11c and the second n-type semiconductor layer 12c contain, for example, Si (silicon) as an n-type impurity. The first p-type semiconductor layer 11a and the second p-type semiconductor layer 12a contain, for example, Mg (magnesium) as a p-type impurity. The first active layer 11b and the second active layer 12b are emission layers that emit light and have, for example, a MQW (multiple quantum well) structure including multiple barrier layers and multiple well layers. The peak wavelength of the light emitted by the first active layer 11b may be the same as or different from the peak wavelength of the light emitted by the second active layer 12b.

The intermediate layer 13 includes at least either a p-type semiconductor layer having a higher p-type impurity concentration than that of the second p-type semiconductor layer 12a or an n-type semiconductor layer having a higher n-type impurity concentration than that of the first n-type semiconductor layer 11c. The intermediate layer 13 functions as a tunnel junction layer, for example.

In the light emitting element 100, the second active layer 12b is larger in area than the first active layer 11b in a plan view.

The semiconductor stack structure 10 has a first opening 16 and a second opening 17. The first opening 16 is provided continuously in the first p-type semiconductor layer 11a and the first active layer 11b. The first opening 16 is a hole that passes through the first p-type semiconductor layer 11a and the first active layer 11b in the Z direction. In the light emitting element 100, the first opening 16 is provided continuously in the first p-type semiconductor layer 11a, the first active layer 11b, and the first n-type semiconductor layer 11c. In the light emitting element 100, the first opening 16 is a hole that passes through the first p-type semiconductor layer 11a and the first active layer 11b before reaching the first n-type semiconductor layer 11c in the Z direction. The first opening 16 does not pass through the first n-type semiconductor layer 11c. In the light emitting element 100, the semiconductor stack structure 10 has multiple first openings 16. The semiconductor stack structure 10 has at least one first opening 16.

The second opening 17 is provided continuously in the first p-type semiconductor layer 11a, the first active layer 11b, the first n-type semiconductor layer 11c, the intermediate layer 13, the second p-type semiconductor layer 12a, and the second active layer 12b. The second opening 17 is a hole that passes through the first p-type semiconductor layer 11a, the first active layer 11b, the first n-type semiconductor layer 11c, the intermediate layer 13, the second p-type semiconductor layer 12a, and the second active layer 12b. In the light emitting element 100, the second opening 17 is continuously provided in the first p-type semiconductor layer 11a, the first active layer 11b, the first n-type semiconductor layer 11c, the intermediate layer 13, the second p-type semiconductor layer 12a, the second active layer 12b, and the second n-type semiconductor layer 12c. In the light emitting element 100, the second opening 17 is a hole that passes through the first p-type semiconductor layer 11a, the first active layer 11b, the first n-type semiconductor layer 11c, the intermediate layer 13, the second p-type semiconductor layer 12a, and the second active layer 12b before reaching the second n-type semiconductor layer 12c in the Z direction. The second opening 17 does not pass through the second n-type semiconductor layer 12c. In the light emitting element 100, the semiconductor stack structure 10 has multiple second openings 17. The semiconductor stack structure 10 has at least one second opening 17. The second opening 17 is provided at a location that overlaps the first opening 16 in a plan view.

In the light emitting element 100, the plan view shape of each of the first openings 16 and the second openings 17 is a perfect circle. The plan view shape of each of the first openings 16 and the second openings 17 may be a semicircle, ellipse, polygon, or the like. In the case in which the shape of each of the first openings 16 and the second openings 17 is a perfect circle, the diameter of a first opening 16 is, for example, 15 μm or smaller, preferably 10 μm to 15 μm, and the diameter of a second opening 17 is, for example, smaller than 12 μm, preferably 5 μm to 10 μm.

In the light emitting element 100, the second connection part 32a where the second electrode 32 is in contact with the second n-type semiconductor layer 12c in a second opening 17 is surrounded by the first connection part 31a where the first electrode 31 is in contact with the first n-type semiconductor layer 11c in the first opening 16 that overlaps the second opening 17 in a plan view.

At least a portion of the upper face of the semiconductor stack structure 10 has multiple projections, for example. As shown in FIG. 2, the projections are arranged to overlap the first active layer 11b and the second active layer 12b in the Z direction. The projections provided on the upper face of the semiconductor stack structure 10 can increase the extraction efficiency of the light emitted upwards from the semiconductor stack structure 10. The upper face of the semiconductor stack structure 10 is the upper face of the second n-type semiconductor layer 12c. The projections may be provided not only in the region that overlaps both the first active layer 11b and the second active layer 12b, but also in the region that overlaps only the second active layer 12b.

The first pad electrode 21 is electrically connected to the first p-type semiconductor layer 11a. For example, the first pad electrode 21 is positioned apart from the semiconductor stack structure 10 in a plan view. The first pad electrode 21 does not overlap the semiconductor stack structure 10 in the Z direction, for example. The first pad electrode 21 may overlap the semiconductor stack structure 10 in the Z direction.

The second pad electrode 22 is electrically connected to the first n-type semiconductor layer 11c. For example, the second pad electrode 22 is positioned apart from the semiconductor stack structure 10 in a plan view. In the example of FIG. 2, the second pad electrode 22 does not overlap the semiconductor stack structure 10 in the Z direction. However, the second pad electrode 22 may overlap the semiconductor stack structure 10 in the Z direction. For example, the second pad electrode 22 may be provided at a location opposite the first pad electrode 21 with the semiconductor stack structure 10 interposed between the second pad electrode 22 and the first pad electrode 21 in a plan view.

The lower electrode 23 is electrically connected to the second n-type semiconductor layer 12c. The lower electrode 23 is provided under the semiconductor stack structure 10, for example. In the light emitting element 100, the lower electrode 23 is disposed at the lowermost portion of the light emitting element 100. In the light emitting element 100, the lower electrode 23 is placed under the semiconductor stack structure 10, the first pad electrode 21, the second pad electrode 22, the first electrode 31, the second electrode 32, the connection electrode 35, and the insulation layer 45. The light emitting element 100 is mounted on a substrate or the like by bonding the lower electrode 23 and the substrate with a bonding material, such as solder.

The first pad electrode 21 and the second pad electrode 22 are each formed of a metal material, for example. For the metal material, at least one of metals, such as Ti (titanium), Pt (platinum), Rh (rhodium), Au (gold), Ni (nickel), Ta (tantalum), Zr (zirconium), and alloys containing these metals can be used. The first pad electrode 21 and the second pad electrode 22 may each be a single layer, or a multilayer structure in which multiple layers are stacked. The first pad electrode 21 and the second pad electrode 22 can each be a multilayer structure in which a Ti layer, a Pt layer, and an Au layer are stacked in that order, for example.

The lower electrode 23 is formed of at least either a metal material or semiconductor material, for example. For the metal material, the same metal material used for the first pad electrode 21 and the second pad electrode 22 can be used. For the semiconductor material, for example, Si can be used. The lower electrode 23 may be, for example, a multilayer structure in which a layer formed of a semiconductor material is stacked on a metal layer.

The first electrode 31 electrically connects the second pad electrode 22 and the first n-type semiconductor layer 11c. The first electrode 31 is located in the first openings 16. The first electrode 31 is not located in the second openings 17. In the light emitting element 100, the first electrode 31 extends from the area under the second pad electrode 22 to the area under the first n-type semiconductor layer 11c. In the light emitting element 100, the first electrode 31 and the first n-type semiconductor layer 11c are electrically connected by coming into contact with one another at the first connection parts 31a.

The second electrode 32 electrically connects the lower electrode 32 and the second n-type semiconductor layer 12c. The second electrode 32 is located in the first openings 16 and the second openings 17. In the light emitting element 100, the second electrode 32 is provided under the second n-type semiconductor layer 12c. In the light emitting element 100, the lower electrode 23 and the second n-type semiconductor layer 12c are electrically connected as the second electrode 32 and the second n-type semiconductor layer 12c come into contact with one another at the second connection parts 32a.

The connection electrode 35 electrically connects the first pad electrode 21 and the first p-type semiconductor layer 11a. In the light emitting element 100, the connection electrode 35 extends from the area under the first pad electrode 21 to the area under the first p-type semiconductor layer 11a. In the light emitting element 100, the connection electrode 35 and the first p-type semiconductor layer 11a are electrically connected via the interlayer electrode 25 positioned between the connection electrode 35 and the first p-type semiconductor layer 11a.

The first electrode 31, the second electrode 32, and the connection electrode 35 are each formed of a metal material, for example. For the metal material, for example, at least one of metals, such as Au (gold), Pt (platinum), Pd (palladium), Rh (rhodium), Ni (nickel), W (tungsten), Mo (molybdenum), Cr (chromium), Ti (titanium), Al (aluminum), Cu (copper), In (indium), Pb (zinc), and alloys containing these metals can be used. The first electrode 31, the second electrode 32, and the connection electrode 35 may each be a single layer, or a stack structure in which multiple layers are stacked. The first electrode 31, the second electrode 32, and the connection electrode 35 may each be a stack structure in which a Ti layer, an Al alloy layer, a Ti layer, a Pt layer, an Au layer, and a Ti layer are stacked in that order, for example.

The insulation layer 45 is disposed between the first electrode 31 and the second electrode 32. The insulation layer 45 electrically isolates the first electrode 31 from the second electrode 32.

The insulation layer 45 is formed of an insulation material. For the insulation material, for example, at least one of silicon oxide, silicon nitride, and silicon oxynitride can be used.

The light emitting element 100 further includes an interlayer insulation film 50. The interlayer insulation film 50 is disposed between the semiconductor stack structure 10 and the first electrode 31, between the semiconductor stack structure 10 and the second electrode 32, and between the semiconductor stack structure 10 and the connection electrode 35. A portion of the interlayer insulation film 50 is disposed between the semiconductor stack structure 10 and the second electrode 32 in a first opening 16. The portion of the interlayer insulation film 50 surrounds the first electrode 31 in a plan view. Another portion of the interlayer insulation film 50 is disposed between the first electrode 31 and the connection electrode 35, electrically isolating the first electrode 31 from the connection electrode 35. Another portion of the interlayer insulation film 50 is disposed between the second electrode 32 and the connection electrode 35, electrically isolating the second electrode 32 from the connection electrode 35.

The interlayer insulation film 50 is formed of an insulation material, for example. For the insulation material, for example, at least one of silicon oxide, silicon nitride, and silicon oxynitride can be used.

The light emitting element 100 further incudes a protective film 55. The protective film 55 is disposed on the semiconductor stack structure 10. The protective film 55 protects the semiconductor stack structure 10. For example, the thickness of the protective film 55 at the location that overlaps the projections of the upper face of the semiconductor stack structure 10 is preferably smaller than the thickness of the protective film 55 located elsewhere. This can increase the extraction efficiency of the light emitted upwards by the semiconductor stack structure 10.

The protective film 55 is formed of an insulation material, for example. For the insulation material, for example, an oxide or nitride containing at least one selected from the group consisting of Si (silicon), Ti (titanium), Zr (zirconium), Nb (niobium), Ta (tantalum), Al (aluminum), and Hf (hafnium) can be used. For the insulation material, for example, at least one of silicon oxide, silicon nitride, and silicon oxynitride can be used.

As shown in FIG. 1 and FIG. 2, in the light emitting element 100, the contact area between the first electrode 31 and the first n-type semiconductor layer 11c in a first opening 16 is larger than the contact area between the second electrode 32 and the second n-type semiconductor layer 12c in a second opening 17 in a plan view. The contact area between the second electrode 32 and the second n-type semiconductor layer 12c in a second opening 17 is preferably 10% or more, but less than 100% of the contact area between the first electrode 31 and the first n-type semiconductor layer 11c in a first opening 16, for example. In the case in which the semiconductor stack structure 10 has multiple first openings 16 and multiple second openings 17, the sum of the contact areas between the first electrode 31 and the first n-type semiconductor layer 11c in the first openings 16 is preferably larger than the sum of the contact areas between the second electrode 32 and the second n-type semiconductor layer 12c in the second openings 17 in a plan view. In the case in which the semiconductor stack structure 10 has multiple first openings 16 and multiple second openings 17, the contact area between the first electrode 31 and the first n-type semiconductor layer 11c at each of the first openings 16 is preferably larger than the contact area between the second electrode 32 and the second n-type semiconductor layer 12c at each of the second openings 17 in a plan view.

In the light emitting element 100, the areas of the first openings 16 in a plan view are the same. In the light emitting element 100, the areas of the second openings 17 in a plan view are the same. The areas of the first openings 16 in a plan view may be different from one another. The areas of the second openings 17 in a plan view may be different from one another.

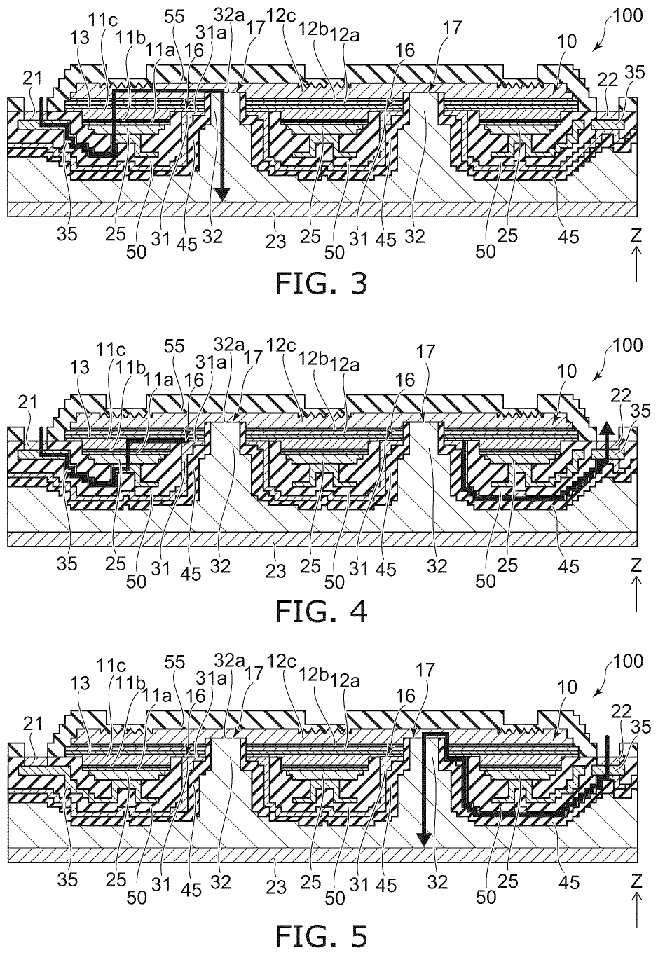

FIG. 3 is a cross-sectional view showing the current path in a first emission state of a light emitting element according to the first embodiment.

FIG. 4 is a cross-sectional view showing the current path in a second emission state of the light emitting element according to the first embodiment.

FIG. 5 is a cross-sectional view showing the current path in a third emission state of the light emitting element according to the first embodiment.

As shown in FIG. 3 to FIG. 5, the light emitting element 100 is allowed to emit light in three emission states, i.e., the first emission state, the second emission state, and the third emission state.

The first emission state is a state in which both the first active layer 11b and the second active layer 12b are allowed to emit light. FIG. 3 shows the current path in the first emission state. As shown in FIG. 3, in the first emission state, the first pad electrode 21 functions as the positive electrode and the lower electrode 23 functions as the negative electrode. An electric current flows from the first pad electrode 21 through the connection electrode 35, the interlayer electrode 25, the first p-type semiconductor layer 11a, the first active layer 11b, the first n-type semiconductor layer 11c, the intermediate layer 13, the second p-type semiconductor later 12a, the second active layer 12b, the second n-type semiconductor layer 12c, and the second electrode 32 to the lower electrode 23. This allows both the first active layer 11b and the second active layer 12b to emit light.

The second emission state is a state in which the first active layer 11b is allowed to emit light, but the second active layer 12b is not. FIG. 4 shows the current path in the second emission state. As shown in FIG. 4, in the second emission state, the first pad electrode 21 functions as the positive electrode and the second pad electrode 22 functions as the negative electrode. An electric current flows from the first pad electrode 21 through the connection electrode 35, the interlayer electrode 25, the first p-type semiconductor layer 11a, the first active layer 11b, the first n-type semiconductor layer 11c, the first electrode 31, and the connection electrode 35 to the second pad electrode 22. This allows the first active layer 11b to emit light without allowing the second active layer 12b to emit light.

The third emission state is a state in which the second active layer 12b is allowed to emit light, but the first active layer 11b is not. FIG. 5 shows the current path in the third emission state. As shown in FIG. 5, in the third emission state, the second pad electrode 22 functions as the positive electrode and the lower electrode 23 functions as the negative electrode. An electric current flows from the second pad electrode 22 through the connection electrode 35, the first electrode 31, the first n-type semiconductor layer 11c, the intermediate layer 13, the second p-type semiconductor later 12a, the second active layer 12b, the second n-type semiconductor layer 12c, and the second electrode 32 to the lower electrode 23. This allows the second active layer 12b to emit light without allowing the first active layer 11b to emit light.

In the case of providing negative electrodes that individually correspond to the first active layer 11b and the second active layer 12b, a large distance between the negative electrodes can cause the current density of the first active layer 11b to differ from that of the second active layer 12b to readily allow for light distribution nonuniformity. In the light emitting element 100, the second openings 17 are arranged to overlap the first openings 16 in a plan view where the first electrode 31 is located in the first openings 16 and the second electrode 32 is located in the first openings 16 and the second openings 17. This can reduce the distance between the first electrode 31, which functions as the negative electrode when the first active layer 11b is allowed to emit light, and the second electrode 32, which functions as the negative electrode when the second active later 12b is allowed to emit light, thereby reducing the current density variation between the first active layer 11b and the second active layer 12b. This thus can reduce the light distribution variation between the first active layer 11b and the second active layer 12b.

In the case of allowing the second active layer 12b to emit light as in the third emission state, the intermediate layer 13 present in the current path tends to increase the forward voltage VF. In the case of a light emitting element 100 having a semiconductor stack structure 10 formed by successively depositing, on a growth substrate, a second n-type semiconductor layer 12c, a second active layer 12b, a second p-type semiconductor layer 12a, a first n-type semiconductor layer 11c, a first active layer 11b, and a first p-type semiconductor layer 11a, the crystallinity of the first active layer 11b tends to be inferior to that of the second active layer 12b. For this reason, when the first active layer 11b is allowed to emit light as in the second emission state, the forward voltage VF readily becomes higher than that in the case in which the second active layer 12b is allowed to emit light as in the third emission state. Accordingly, in the light emitting element 100, setting the contact area between the first electrode 31 and the first n-type semiconductor layer 11c in a first opening 16 larger than the contact area between the second electrode 32 and the second n-type semiconductor layer 12c in a second opening 17 can reduce the forward voltage VF in the first electrode 31 thereby improving the light intensity in the second and third emission states.

In the light emitting element 100, moreover, each second connection part 32a is surrounded by a first connection part 31a. This can bring the in-plane light distribution property of the first active layer 11b close to that of the second active layer 12b as compared to the case of locating the first openings 16 and the second openings 17 so as not to overlap and providing the first connection parts 31a and the second connection parts 32a, respectively.

In the light emitting element 100, furthermore, the light emission of first active layer 11b and the light emission of the second active layer 12b can be controlled individually. Accordingly, in the case in which the peak wavelength of the light from the first active layer 11b differs from the peak wavelength of the light from the second active layer 12b, the peak wavelength of the light from the light emitting element can be switched by switching the active layer that is allowed to emit light. For example, in the case in which the peak wavelength of the light from the first active layer 11b is the same as the peak wavelength of the light from the second active layer 12b, the active layer 11b and the second active layer 12b can be used alternately by switching the active layer that is allowed to emit light. This can reduce the impact of the heat on the first active layer 11b and the second active layer 12b thereby reducing the shifting of the peak wavelength attributable to the heat generated by the semiconductor stack structure 10 as compared to the case in which a single active layer is allowed to emit light. For example, in the case in which the first active layer 11b and the second active layer 12b emit ultraviolet light, the first active layer 11b and the second active layer 12b are easily affected by the heat. Thus, switching between the active layers for light emission can be particularly effective in reducing the impact of the heat on the active layers.

### Variation

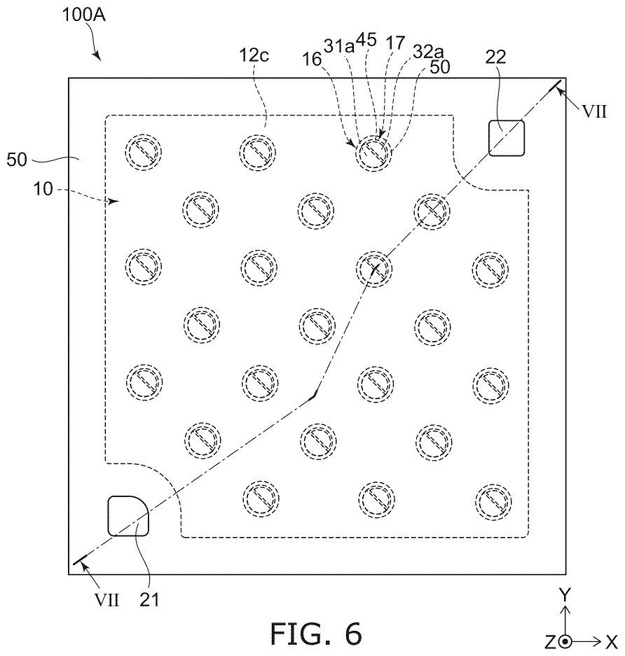

FIG. 6 is a plan view showing a light emitting element according to a variation of the first embodiment.

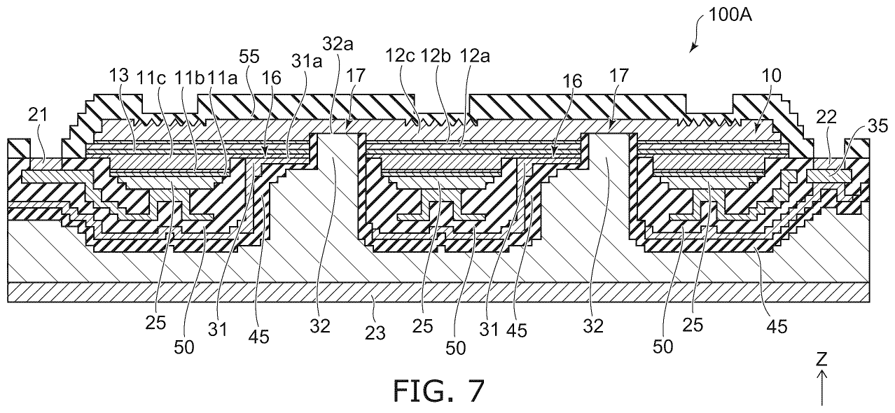

FIG. 7 is a cross-sectional view showing the light emitting element according to the variation of the first embodiment.

FIG. 7 is a cross section taken along line VII-VII in FIG. 6.

As shown in FIG. 6 and FIG. 7, in a light emitting element 100A according to the variation of the first embodiment, the shapes of the first openings 16 and the second openings 17 and the positions of the first connection parts 31a and the second connection parts 32a differ from those of the light emitting element 100. The light emitting element 100A is the same as the light emitting element 100 otherwise.

In the light emitting element 100A, the plan view shape of each second opening 17 is a semicircle. In the light emitting element 100A, moreover, the second connection parts 32a are not surrounded by the first connection parts 31a.

In the light emitting element 100A, similar to the light emitting element 100, the second opening 17 is positioned to overlap the first opening 16, the first electrode 31 is located in the first opening 16, and the second electrode 32 is located in the first opening 16 and the second opening 17 to thereby reduce the light distribution variation between the first active layer 11b and the second active layer 12b.

### Second Embodiment

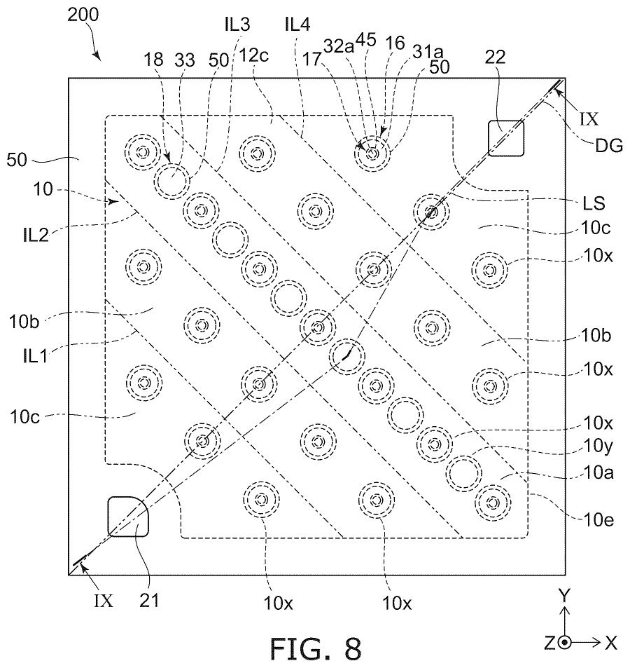

FIG. 8 is a plan view showing a light emitting element according to a second embodiment.

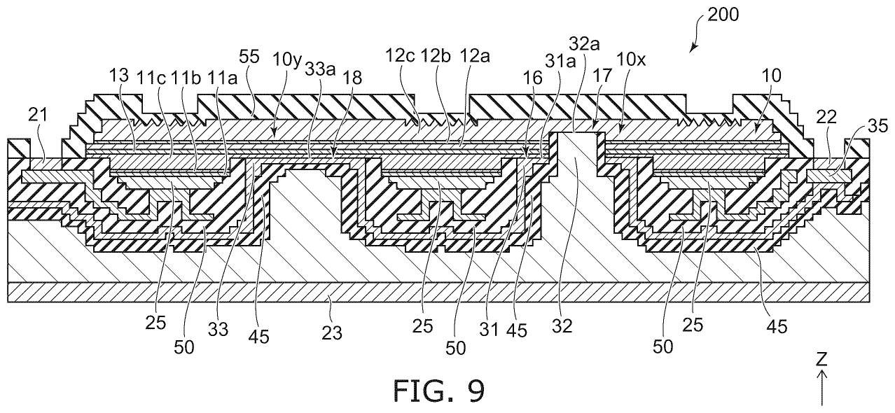

FIG. 9 is a cross-sectional view showing the light emitting element according to the second embodiment.

FIG. 9 is a cross section taken along line IX-IX in FIG. 8.

As shown in FIG. 8 and FIG. 9, a light emitting element 200 according to the second embodiment primarily differs from the light emitting element 100 such that the semiconductor stack structure 10 further includes third openings 18 and a third electrode 33. The light emitting element 200 essentially has the same structure as the light emitting element 100 described above otherwise.

As shown in FIG. 8 and FIG. 9, the semiconductor stack structure 10 has a first region 10x and a second region 10y in a plan view. The second region 10y does not overlap the first region 10x in the plan view. A first opening 16 and a second opening 17 are located in the first region 10x. A third opening 18 is located in the second region 10y. The third opening 18 does not overlap the first opening 16 and the second opening 17 in the plan view.

A third opening 18 is provided continuously in the first p-type semiconductor layer 11a and the first active layer 11b. The third opening 18 is a hole that passes through the first p-type semiconductor layer 11a and the first active layer 11b in the Z direction. In the light emitting element 200, the third opening 18 is provided continuously in the first p-type semiconductor layer 11a, the first active layer 11b, and the first n-type semiconductor layer 11c. In the light emitting element 200, the third opening 18 is a hole that passes through the first p-type semiconductor layer 11a and the first active layer 11b before reaching the first n-type semiconductor layer 11c in the Z direction. The third opening 18 does not pass through the first n-type semiconductor layer 11c. In the light emitting element 200, the semiconductor stack structure 10 has multiple third openings 18. In the light emitting element 200, the semiconductor stack structure 10 has at least one third opening 18.

In the light emitting element 200, the plan view shape of a third opening 18 is a perfect circle. The plan view shape of a third opening 18 may be a semicircle, ellipse, polygon, or the like.

The third electrode 33 electrically connects the second pad electrode 22 and the first n-type semiconductor layer 11c. The third electrode 33 is located in a third opening 18. The third electrode 33 is connected to the first electrode 31. The third electrode 33 is essentially the same as the first electrode 31 except for the location which is in the third opening 18. In other words, the third electrode 33 is an electrode that corresponds to the first electrode 31 in a second region 10y. In the light emitting element 200, the third electrode 33 and the first n-type semiconductor layer 11c are electrically connected by being in contact with one another at a third connection part 33a. The material for the third electrode 33 may be the same as that for the first electrode 31.

As shown in FIG. 8, in the plan view, the semiconductor stack structure 10 has one central region 10a, two intermediate regions 10b, and two outer regions 10c. The central region 10a in the plan view is located halfway between the first pad electrode 21 and the second pad electrode 22. The central region 10a includes the center of the semiconductor stack structure 10 in the plan view, for example. One of the intermediate regions 10b is located between the central region 10a and the first pad electrode 21, and the other between the central region 10a and the second pad electrode 22. One of the outer regions 10c is located between one of the intermediate regions 10b and the first pad electrode 21, and the other between the other intermediate region 10b and the second pad electrode 22.

In the plan view, the portion of the diagonal line DG of the light emitting element 200 passing through the first pad electrode 21 and the second pad electrode 22 that overlaps the semiconductor stack structure 10 is designated as the first line section LS. The four straight lines orthogonal to the first line section LS are designated as the first line IL1, second line IL2, third line IL3, and fourth line IL4 from the first pad electrode 21 side. The first line section LS is equally divided into five sections by the first line IL1, the second line IL2, the third line IL3, and the fourth line IL4. The central region 10a is the region of the semiconductor stack structure 10 that is located between the second line IL2 and the third line IL3 in the plan view. The intermediate regions 10b are the region of the semiconductor stack structure 10 located between the first line IL1 and the second line IL2 and the region of the semiconductor stack structure 10 located between the third line IL3 and the fourth line IL4 in the plan view. One of the outer regions 10c is the region of the semiconductor stack structure 10 located between the first line ILI and the outer edge 10e of the semiconductor stack structure 10, and the other one of the outer regions 10c is the region of the semiconductor stack structure 10 located between the fourth line IL4 and the outer edge 10e of the semiconductor stack structure 10 in the plan view. The outer regions 10c are positioned outward from the intermediate regions 10b using the center of the semiconductor stack structure 10 as a reference.

A second region 10y is located in the central region 10a, for example. In the light emitting element 200, the second regions 10y are located in the central region 10a and not located in the intermediate regions 10b and the outer regions 10c. In other words, in the light emitting element 200, the third electrode 33 is in contact with the first n-type semiconductor layer 11c in the central region 10a, and not in contact with the first n-type semiconductor layer 11c in the intermediate regions 10b and the outer regions 10c. In the light emitting element 200, moreover, the first regions 10x are located in the central region 10a, the intermediate regions 10b, and the outer regions 10c. In other words, in the light emitting element 200, the first electrode 31 is in contact with the first n-type semiconductor layer 11c in the central region 10a, the intermediate regions 10b, and the outer regions 10c. In the light emitting element 200, the second electrode 32 is in contact with the second n-type semiconductor layer 12c in the central region 10a, the intermediate regions 10b, and the outer regions 10c.

In the light emitting element 200, the first openings 16 and the third openings 18 are alternately arranged in the central region 10a. The layout of the first openings 16 and the third openings 18 is not limited to this. For example, the layout may be such that two or more third openings 18 may be provided between two first openings 16, or one third opening 18 between two first openings 16 in part while two or more third openings 18 between two first openings 16 in part.

In the light emitting element 200, the second openings 17 and the third openings 18 are alternately arranged in the central region 10a. The layout of the second openings 17 and the third openings 18 is not limited to this. For example, the layout may be such that two or more third openings 18 may be provided between two second openings 17, or one third opening 18 between two second openings 17 in part while two or more third openings 18 between two second openings 17 in part.

As described above, in the light emitting element 200, the first openings 16 and the second openings 17 are located in the first regions 10x, the third openings 18 are located in the second regions 10y which do not overlap the first regions 10x in a plan view, and the third electrode 33 is located in the third openings 18. In the case of a light emitting element 200 having a semiconductor stack structure formed by successively depositing, on a growth substrate, a second n-type semiconductor layer 12c, a second active layer 12b, a second p-type semiconductor layer 12a, a first n-type semiconductor layer 11c, a first active layer 11b, and a first p-type semiconductor layer 11a, the first p-type semiconductor layer 11a, the first active layer 11b, and the first n-type semiconductor layer 11c tend to have inferior crystallinity to the second p-type semiconductor layer 12a, the second active layer 12b, and the second n-type semiconductor layer 12c, and are less bright. Accordingly, placing the third electrode 33 that is in contact with the first n-type semiconductor layer 11c separately from the first electrode 31 can increase the contact areas between the first n-type semiconductor layer 11c and the electrodes, thereby improving the light intensity when allowing the first active layer 11b to emit light.

The central region 10a that is located farther away from the first pad electrode 21 and the second pad electrode 22 than the intermediate regions 10b and the outer regions 10c are tends to have a lower current density than the intermediate regions 10b and the outer regions 10c. Accordingly, locating the third openings 18 (the third electrode 33) in the second regions 10y located in the central region 10a can improve the light intensity in the central region 10a which readily has a lower current density than the intermediate regions 10b and the outer regions 10c. This can reduce the in-plane light distribution nonuniformity of the semiconductor stack structure 10.

### Variation

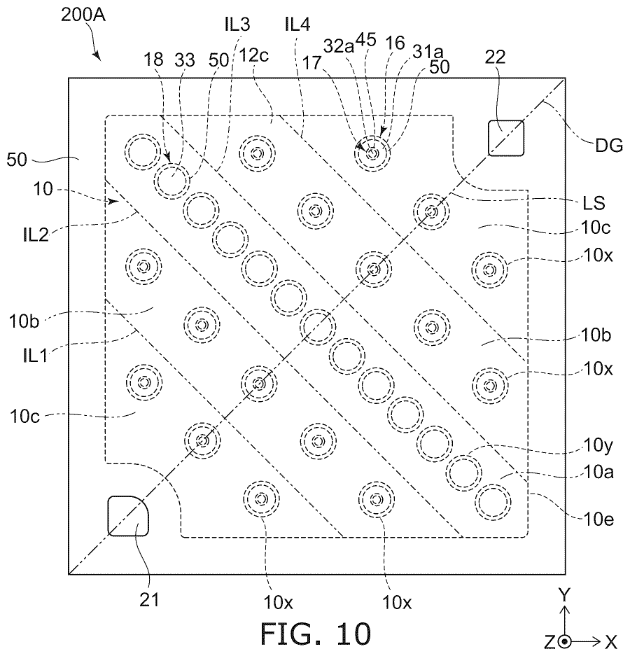

FIG. 10 is a plan view of a light emitting element according to a variation of the second embodiment.

As shown in FIG. 10, a light emitting element 200A according to the variation of the second embodiment primarily differs from the light emitting element 200 in terms of the layout of the first openings 16, the second openings 17, and the third openings 18 in the plan view. The light emitting element 200A has practically the same structure as that of the light emitting element 200 described above otherwise.

In the light emitting element 200A, the second regions 10y are located in the central region 10a, and not in the intermediate regions 10b and the outer regions 10c. In other words, in the light emitting element 200A, the third electrode 33 is in contact with the first n-type semiconductor layer 11c in the central region 10a, and not in contact with the first n-type semiconductor layer 11c in the intermediate regions 10b and the outer regions 10c. In the light emitting element 200A, the first regions 10x are located in the intermediate regions 10b and the outer regions 10c, and not located in the central region 10a. In other words, in the light emitting element 200A, the first electrode 31 is in contact with the first n-type semiconductor layer 11c in the intermediate regions 10b and the outer regions 10c, and not in contact with the first n-type semiconductor layer 11c in the central region 10a. In the light emitting element 200A, the second electrode 32 is in contact with the second n-type semiconductor layer 12c in the intermediate regions 10b and the outer regions 10c, and not in contact with the second n-type semiconductor layer 12c in the central region 10a.

In the case of a light emitting element 200A having a semiconductor stack structure formed by successively depositing, on a growth substrate, a second n-type semiconductor layer 12c, a second active layer 12b, a second p-type semiconductor layer 12a, a first n-type semiconductor layer 11c, a first active layer 11b, and a first p-type semiconductor layer 11a, the light intensity when allowing the first active layer 11b to emit light can be similarly improved by locating the third electrode 33 in the third openings 18.

### Third Embodiment

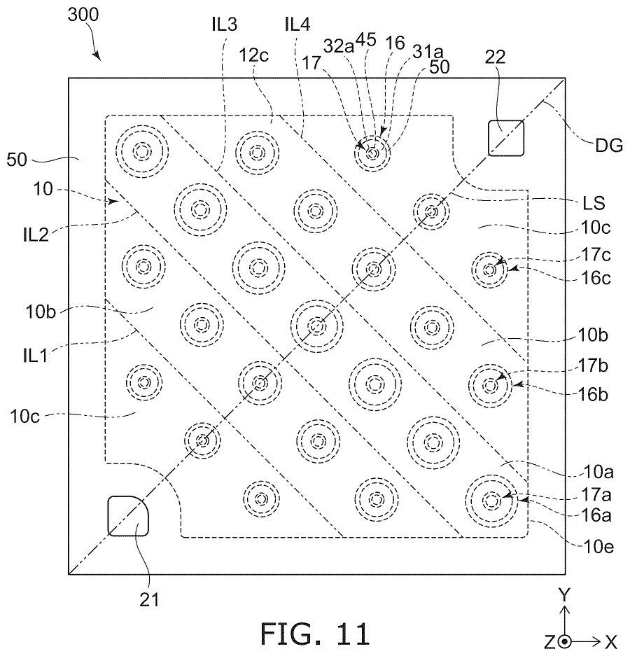

FIG. 11 is a plan view showing a light emitting element according to a third embodiment.

As shown in FIG. 11, in the light emitting element 300 according to the third embodiment, the plan view areas of the first openings 16 and the second openings 17 are different from those in the light emitting element 100. The light emitting element 300 has essentially the same structure as the light emitting element 100 described above otherwise.

As shown in FIG. 11, in the plan view, the semiconductor stack structure 10 has a central region 10a, intermediate regions 10b, and outer regions 10c. The positional relationship of the central region 10a, the intermediate regions 10b, and the outer regions 10c is the same as that of the central region 10a, the intermediate regions 10b, and the outer regions 10c in the light emitting element 200 described above.

The first openings 16 include multiple first central openings 16a, multiple first intermediate openings 16b, and multiple first outer openings 16c. The first central openings 16a are located in the central region 10a. The first intermediate openings 16b are located in the intermediate regions 10b. The first outer openings 16c are located in the outer regions 10c.

The second openings 17 include multiple second central openings 17a, multiple second intermediate openings 17b, and multiple second outer openings 17c. The second central openings 17a are located in the central region 10a. The second intermediate openings 17b are located in the intermediate regions 10b, and the second outer openings 17c are located in the outer regions 10c.

In the light emitting element 300, each of the first central openings 16a is larger in area than each of the first intermediate openings 16b in a plan view.

Moreover, each of the first intermediate openings 16b is larger in area than each of the first outer openings 16c in a plan view.

In the light emitting element 300, the plan view areas of the first central openings 16a are the same. In the light emitting element 300, the plan view areas of the first intermediate openings 16b are the same. In the light emitting element 300, the plan view areas of the first outer openings 16c are the same. The plan view areas of the first central openings 16a may be different from one another. The plan view areas of the first intermediate openings 16b may be different from one another. The plan view areas of the first outer openings 16c may be different from one another.

Here, the sum of the plan view areas where the first electrode 31 is in contact with the first n-type semiconductor layer 11c at the first central openings 16a is designated as the total area S_{SUM}a. The sum of the plan view areas where the first electrode 31 is in contact with the first n-type semiconductor layer 11c at the first intermediate openings 16b is designated as the total area S_{SUM}b. The sum of the plan view areas where the first electrode 31 is in contact with the first n-type semiconductor layer 11c at the first outer openings 16c is designated as the total area S_{SUM}c. In the light emitting element 300, the total area S_{SUM}a is larger than the total area S_{SUM}b (S_{SUM}a>S_{SUM}b). The total area S_{SUM}b is larger than the total area S_{SUM}c (S_{SUM}b>S_{SUM}c).

In the light emitting element 300, the plan view area of each of the second central openings 17a is larger than the plan view area of each of the second intermediate openings 17b. The plan view area of each of the second intermediate openings 17b is larger than the plan view area of each of the second outer openings 17c.

In the light emitting element 300, the plan view areas of the second central openings 17a are the same. In the light emitting element 300, the plan view areas of the second intermediate openings 17b are the same. In the light emitting element 300, the plan view areas of the second outer openings 17c are the same. The plan view areas of the second central openings 17a may be different from one another. The plan view areas of the second intermediate openings 17b may be different from one another. The plan view areas of the second outer openings 17c may be different from one another.

Here, the area of contact between the second electrode 32 and the second n-type semiconductor layer 12c at one of the second central openings 17a in a plan view is designated as an area S2a. The area of contact between the first electrode 31 and the first n-type semiconductor layer 11c at one of the first central openings 16a in a plan view is designated as an area S1a. The area of contact between the second electrode 32 and the second n-type semiconductor layer 12c at one of the second intermediate openings 17b in a plan view is designated as an area S2b. The area of contact between the first electrode 31 and the first n-type semiconductor layer 11c at one of the first intermediate openings 16b in a plan view is designated as an area S1b. The area of contact between the second electrode 32 and the second n-type semiconductor layer 12c at one of the second outer openings 17c in a plan view is designated as an area S2c. The area of contact between the first electrode 31 and the first n-type semiconductor layer 11c at one of the first outer openings 16c in a plan view is designated as an area S1c. In the light emitting element 300, the ratio of the area S1a to the area S2a (S1a/S2a) is the same as the ratio of the area S1b to the area S2b (S1b/S2b) and the ratio of the area S1c to the area S2c (S1c/S2c) (S1a/S2a=S1b/S2b=S1c/S2c).

The central region 10a tends to have a lower current density than the intermediate regions 10b. The intermediate regions 10b tend to have a lower current tensity than the outer regions 10c. Accordingly, in the light emitting element 300, the sum of the areas of contact between the first electrode 31 and the first n-type semiconductor layer 11c at the first openings 16 located in the central region 10a (first central openings 16a) (total area S_{SUM}a) is set to be larger than the sum of the areas of contact between the first electrode 31 and the first n-type semiconductor layer 11c at the first openings 16 located in the intermediate region 10b (first intermediate openings 16b) (total area S_{SUM}b), and the total area S_{SUM}b is set to be larger than the sum of the areas of contact between the first electrode 31 and the first n-type semiconductor layer 11c at the first openings 16 located in the outer regions 10c (first outer openings 16c) (total area S_{SUM}c). This can achieve a high current density in the intermediate regions 10b where the current density tends to be lower than the outer regions 10c, while achieving an even higher current density in the central region 10a which tends to have a lower current density than the intermediate regions 10b. This can reduce the in-plane light distribution nonuniformity of the semiconductor stack structure 10.

In the light emitting element 300, moreover, the electrode and semiconductor layer contact area ratio (S1a/S2a) at each opening in the central region 10a, the electrode and semiconductor layer contact area ratio (S1b/S2b) at each opening in the intermediate regions 10b, and the electrode and semiconductor layer contact area ratio (S1c/S2c) at each opening in the outer regions 10c are set to be the same. This can reduce the current density nonuniformity in the openings, thereby reducing the degradation of semiconductor layers.

### Variation

FIG. 12 is a plan view of a light emitting element according to a variation of the third embodiment.

As shown in FIG. 12, a light emitting element 300A according to the variation of the third embodiment primarily differs from the light emitting element 300 in terms of the sizes of the areas of the first openings 16 and the second openings 17 in a plan view. The light emitting element 300A has essentially the same structure as the light emitting element 300 described above otherwise.

In the light emitting element 300A, similar to the light emitting element 300 described above, the first central openings 16a are larger in area than the first intermediate openings 16b in a plan view. Moreover, the first intermediate openings 16b are larger in area than the first outer openings 16c in a plan view.

In the light emitting element 300A, the plan view area of each of the second central openings 17a is the same as the plan view area of each of the second intermediate openings 17b and the second outer openings 17c.

In the light emitting element 300A, the ratio of the area S1a to the area S2a (S1a/S2a) is higher than the ratio of the area S1b to the area S2b (S1b/S2b) (S1a/S2a>S1b/S2b). Furthermore, the ratio of the area S1b to the area S2b (S1b/S2b) is higher than the ratio of the area S1c to S2c (S1c/S2c) (S1b/S2b>S1c/S2c).

In the light emitting element 300A, similar to the light emitting element 300, the total area S_{SUM}a is larger than the total area S_{SUM}b (S_{SUM}a>S_{SUM}b). Also, the total area S_{SUM}b is larger than the total are S_{SUM}c (S_{SUM}b>S_{SUM}c).

In the light emitting element 300A, the plan view areas of the first central openings 16a are the same. In the light emitting element 300A, the plan view areas of the first intermediate openings 16b are the same. In the light emitting element 300A, the plan view areas of the first outer openings 16c are the same. The plan view areas of the first central openings 16a may be different from one another. The plan view areas of the first intermediate openings 16b may be different from one another. The plan view areas of the first outer openings 16c may be different from one another.

In the light emitting element 300A, the plan view areas of the second central openings 17a are the same. In the light emitting element 300A, the plan view areas of the second intermediate openings 17b are the same. In the light emitting element 300A, the plan view areas of the second outer openings 17c are the same. The plan view areas of the second central openings 17a may be different from one another. The plan view areas of the second intermediate openings 17b may be different from one another. The plan view areas of the second outer openings 17c may be different from one another.

In the light emitting element 300A, the sum of the areas of contact between the first electrode 31 and the first n-type semiconductor layer 11c at the first openings 16 located in the central region 10a (first central openings 16a) (total area S_{SUM}a) is set to be larger than the sum of the areas of contact between the first electrode 31 and the first n-type semiconductor layer 11c at the first openings 16 located in the intermediate region 10b (first intermediate openings 16b) (total area S_{SUM}b). The total area S_{SUM}b is set to be larger than the sum of the areas of contact between the first electrode 31 and the first n-type semiconductor layer 11c at the first openings 16 located in the outer regions 10c (first outer openings 16c) (total area S_{SUM}c). This can reduce the in-plane light distribution nonuniformity of the semiconductor stack structure 10.

In the light emitting element 300A, moreover, the electrode and semiconductor layer contact area ratio (S1a/S2a) at each opening in the central region 10a is set to be higher than the electrode and semiconductor layer contact area ratio (S1b/S2b) at each opening in the intermediate regions 10b. The electrode and semiconductor layer contact area ratio (S1b/S2b) at each opening in the intermediate regions 10b is set to be higher than the electrode and semiconductor layer contact area ratio (S1c/S2c) at each opening in the outer regions 10c. This can reduce the in-plane current density nonuniformity of the semiconductor stack structure 10.

### Manufacturing Method

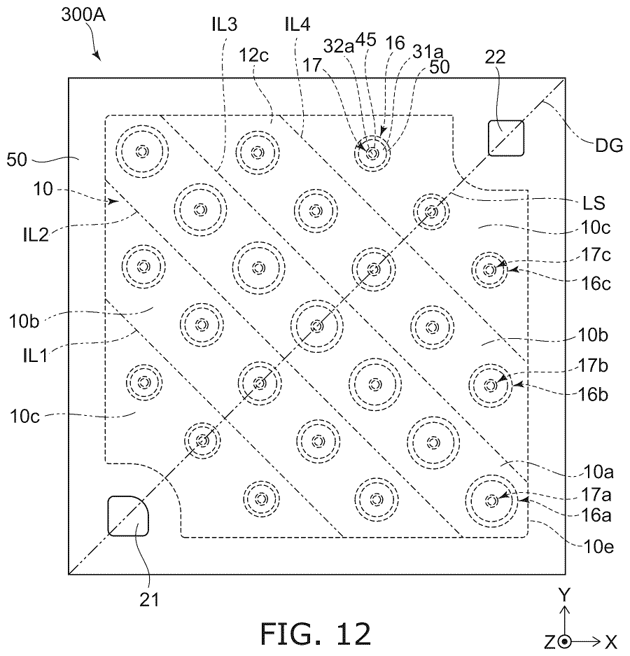

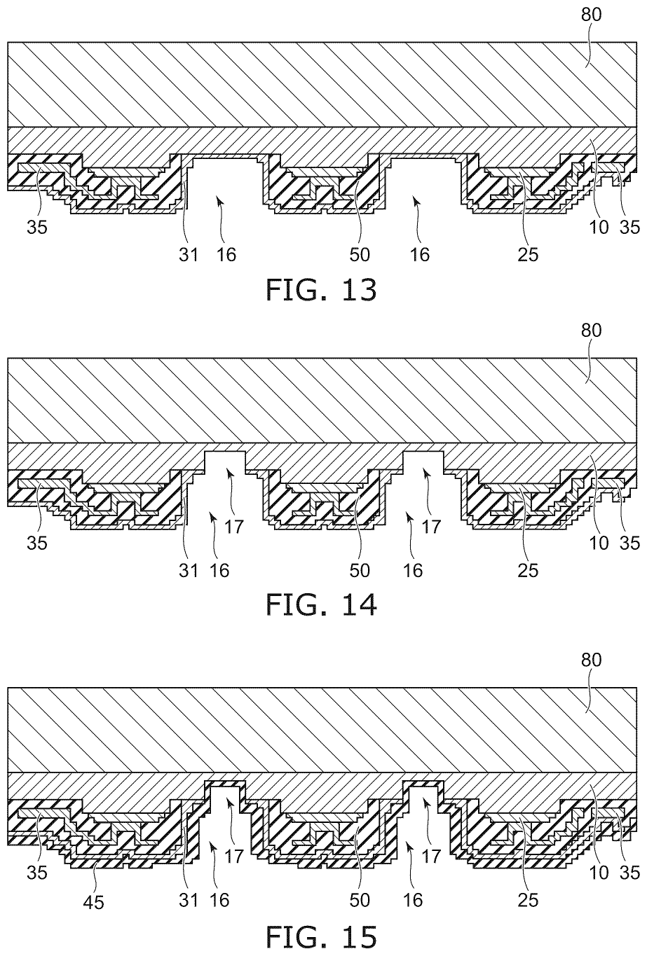

FIG. 13 to FIG. 17 are cross-sectional views each showing a part of a method of manufacturing a light emitting element according to the first embodiment.

In the method of manufacturing a light emitting element 100, a semiconductor stack structure 10 having multiple first openings 16 is formed on a growth substrate 80 first. Then on the semiconductor stack structure 10, an interlayer electrode 25, a connection electrode 35, and an interlayer insulation film 50 are formed. Then a first electrode 31 is formed on the interlayer insulation film 50 and in the first openings 16. By following these steps, a structure having a first electrode 31 located in the first openings 16 is provided as shown in FIG. 13.

Then as shown in FIG. 14, second openings 17 are formed by partially removing the first electrode 31 and the semiconductor stack structure 10 located in the first openings 16.

Then as shown in FIG. 15, an insulation layer 45 is formed on the first electrode 31 and in the second openings 17.

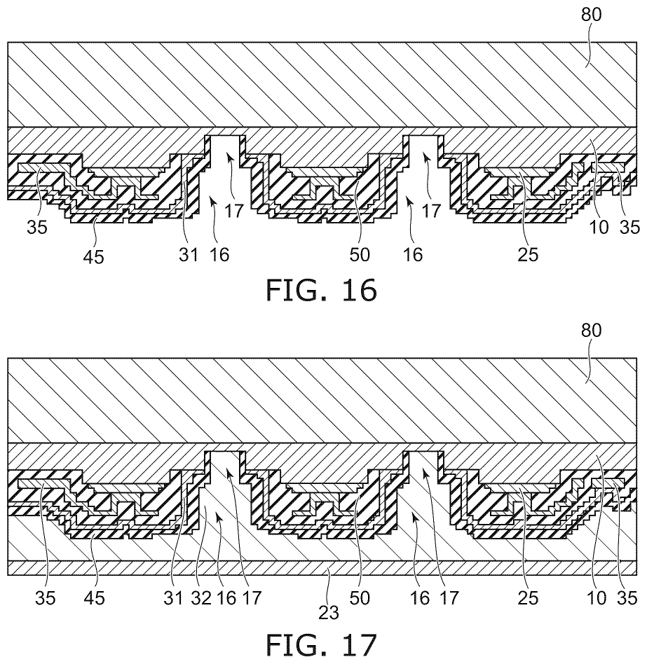

Then as shown in FIG. 16, a portion of the semiconductor stack structure 10 is exposed by partially removing the insulation layer 45.

Then as shown in FIG. 17, a second electrode 32 is formed on the exposed semiconductor stack structure 10 and the insulation layer 45. Then on the second electrode 32, a lower electrode 23 is formed.

Embodiments of the present disclosure may include those described below.

As described above, according to an embodiment of the present disclosure, a light emitting element capable of reducing light distribution variation between the first active layer and the second active layer can be provided.

The embodiments described above are examples that give shape to the present invention, but the present invention is not limited to these embodiments. For example, embodiments resulting from adding to, removing from, or modifying certain constituent elements or processes in the embodiments described above are also encompassed by the present invention. The embodiments described above, moreover, can be implemented in combination with one another.

What is claimed is:

1. A light emitting element comprising:
a semiconductor stack structure comprising:
a first p-type semiconductor layer,
a first active layer disposed on the first p-type semiconductor layer,
a first n-type semiconductor layer disposed on the first active layer,
an intermediate layer disposed on the first n-type semiconductor layer,
a second p-type semiconductor layer disposed on the intermediate layer,
a second active layer disposed on the second p-type semiconductor layer, and
a second n-type semiconductor layer disposed on the second active layer, wherein:
the semiconductor stack structure includes a first opening provided continuously in the first p-type semiconductor layer and the first active layer, and a second opening located to overlap the first opening in a plan view and provided continuously in the first n-type semiconductor layer, the intermediate layer, the second p-type semiconductor layer, and the second active layer;
a first electrode located in the first opening and electrically connected to the first n-type semiconductor layer;
a second electrode located in the first opening and the second opening and electrically connected to the second n-type semiconductor layer; and
an insulation layer disposed between and in contact with the first electrode and the second electrode.

2. The light emitting element according to claim 1, wherein a plan view area of contact between the first electrode and the first n-type semiconductor layer at the first opening is larger than a plan view area of contact between the second electrode and the second n-type semiconductor layer at the second opening.

3. The light emitting element according to claim 1, wherein the second connection part where the second electrode is in contact with the second n-type semiconductor layer at the second opening is surrounded by the first connection part where the first electrode is in contact with the first n-type semiconductor layer at the first opening.

4. The light emitting element according to claim 1, wherein:
the semiconductor stack structure comprises a first region and a second region not overlapping the first region in the plan view;
the first opening and the second opening are positioned in the first region;
the semiconductor stack structure further includes a third opening positioned in the second region and provided continuously in the first p-type semiconductor layer and the first active layer; and
the light emitting element further comprises a third electrode located in the third opening and electrically connected to the first n-type semiconductor layer.

5. The light emitting element according to claim 4, further comprising a first pad electrode electrically connected to the first p-type semiconductor layer; and
a second pad electrode electrically connected to the second n-type semiconductor layer; wherein:
the semiconductor stack structure comprises:
a central region positioned halfway between the first pad electrode and the second pad electrode in the plan view,
a first intermediate region positioned between the central region and the first pad electrode, and a second intermediate region positioned between the central region and the second pad electrode, in the plan view, and
a first outer region positioned between one of the intermediate regions and the first pad electrode, and a second outer region positioned between the other of the intermediate region and the second pad electrode, in the plan view; and
the second region is positioned in the central region.

6. The light emitting element according to claim 1, further comprising:
a first pad electrode electrically connected to the first p-type semiconductor layer; and
a second pad electrode electrically connected to the second n-type semiconductor layer; wherein:
the semiconductor stack structure comprises:
a central region positioned halfway between the first pad electrode and the second pad electrode in the plan view,
a first intermediate region positioned between the central region and the first pad electrode, and a second intermediate region positioned between the central region and the second pad electrode, in the plan view,
a first outer region positioned between one of the intermediate regions and the first pad electrode, and a second outer region positioned between the other of the intermediate regions and the second pad electrode, in the plan view;
the semiconductor stack structure includes a plurality of the first openings, which include:
a plurality of first central openings located in the central region,
a plurality of first intermediate openings located in the intermediate regions, and
a plurality of first outer openings located in the outer regions;
a sum of plan view areas where the first electrode is in contact with the first n-type semiconductor layer at the first central openings is larger than a sum of plan view areas where the first electrode is in contact with the first n-type semiconductor layer at the first intermediate openings; and
a sum of the plan view areas where the first electrode is in contact with the first n-type semiconductor layer at the first intermediate openings is larger than a sum of plan view areas where the first electrode is in contact with the first n-type semiconductor layer at the first outer openings.

7. The light emitting element according to claim 6, wherein:
the semiconductor stack structure includes a plurality of the second openings, which include:
a plurality of second central openings located in the central region,
a plurality of second intermediate openings located in the intermediate regions, and
a plurality of second outer openings located in the outer regions; and
a ratio of a plan view area of contact between the first electrode and the first n-type semiconductor layer at one of the first central openings to a plan view area of contact between the second electrode and the second n-type semiconductor layer at one of the second central openings is the same as a ratio of a plan view area of contact between the first electrode and the first n-type semiconductor layer at one of the first intermediate openings to a plan view area of contact between the second electrode and the second n-type semiconductor layer at one of the second intermediate openings and a ratio of a plan view area of contact between the first electrode and the first n-type semiconductor layer at one of the first outer openings to a plan view area of contact between the second electrode and the second n-type semiconductor layer at one of the second outer openings.

8. The light emitting element according to claim 6, wherein:
the semiconductor stack structure includes a plurality of the second openings, which include:
a plurality of second central openings located in the central region,
a plurality of second intermediate openings located in the intermediate regions, and
a plurality of second outer openings located in the outer regions; and
a ratio of a plan view area of contact between the first electrode and the first n-type semiconductor layer at one of the first central openings to a plan view area of contact between the second electrode and the second n-type semiconductor layer at one of the second central openings is higher than a ratio of a plan view area of contact between the first electrode and the first n-type semiconductor layer at one of the first intermediate openings to a plan view area of contact between the second electrode and the second n-type semiconductor layer at one of the second intermediate openings; and
a ratio of a plan view area of contact between the first electrode and the first n-type semiconductor layer at one of the first intermediate openings to a plan view area of contact between the second electrode and the second n-type semiconductor layer at one of the second intermediate openings is higher than a ratio of a plan view area of contact between the first electrode and the first n-type semiconductor layer at one of the first outer openings to a plan view area of contact between the second electrode and the second n-type semiconductor layer at one of the second outer openings.

9. The light emitting element according to claim 1, wherein an area of the second active layer is larger than an area of the first active layer in the plan view.
